(19) United States
(12) Patent Application Publication
(10) Pub. No.: US 2023/0098148 A1
(43) Pub. Date: Mar. 30, 2023

(54) ADHESIVE FILM FOR SURFACE PROTECTION AND OPTICAL MEMBER COMPRISING THE SAME

(71) Applicant: SAMSUNG SDI CO., LTD., Yongin-si (KR)

(72) Inventors: Bong Soo PARK, Suwon-si (KR); Young Hoon KIM, Suwon-si (KR); Dong Heon YUN, Suwon-si (KR); Won KIM, Suwon-si (KR); Irina NAM, Suwon-si (KR); Il Jin KIM, Suwon-si (KR); Dong Il HAN, Suwon-si (KR)

(21) Appl. No.: 17/935,807

(22) Filed: Sep. 27, 2022

(30) Foreign Application Priority Data
Sep. 27, 2021 (KR) 10-2021-0127197

(51) Int. Cl. C09J 175/04; C09J 7/10; C09J 11/06

(52) U.S. Cl. CPC C09J 175/04; C09J 7/10; C09J 11/06; C09J 2301/312; C09J 2301/408

(57) ABSTRACT

An adhesive film for surface protection and an optical member including the same are provided. An adhesive film for surface protection is formed of a composition for adhesive films including a curable component including a urethane-based binder, a curing agent, and a plasticizer, and has a peel strength variation rate of −50% to 20%, as calculated by Equation 1.

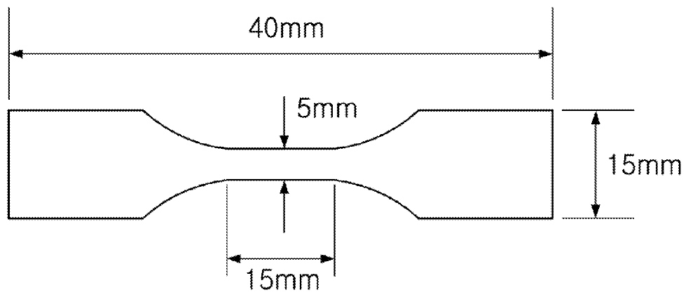

### CROSS-REFERENCE TO RELATED APPLICATION

This application claims priority to and the benefit of Korean Patent Application No. 10-2021-0127197, filed on Sep. 27, 2021 in the Korean Intellectual Property Office, the entire disclosure of which is incorporated herein by reference.

### 1. FIELD

Aspects of embodiments of the present invention relate to an adhesive film for surface protection and an optical member comprising the same.

### 2. DESCRIPTION OF THE RELATED ART

To prevent or reduce generation of defects on a surface of an optical member or an electronic member, such as an LCD, an organic EL display, a touch panel using the same, a lens unit of a camera, an electronic device, and the like, in the course of processing, assembly, inspection, transportation, and the like, a surface protective film is attached to an exposed surface of the optical member or the electronic member. The surface protective film is removed from the optical member or the electronic member when there is no need for surface protection. In recent years, a single surface protective film has been continuously used until final shipment through assembly, inspection, transportation, and the like after the manufacturing process of the optical member or the electronic member.

A surface protective film prepared using a (meth)acrylic resin in an adhesive layer is known in the art. However, since such a surface protective film exhibits poor wettability with respect to the optical member or the electronic member, bubbles can be captured between the member and the surface protective film. In addition, residue of the adhesive layer can remain upon separation of the surface protective film from the member. Thus, a typical surface protective film is not suitable for surface protection of the member, particularly for a surface of the member that can be easily damaged by foreign matter.

In recent years, a surface protective film using a urethane-based adhesive in an adhesive layer has been reported in the art. However, a typical urethane-based adhesive exhibits poor initial wettability with respect to the optical or electronic members to allow easy introduction of bubbles thereinto. In addition, the typical urethane-based adhesive allows significant increase in adhesion over time. Significant increase in adhesion over time of the protective film can make it difficult to remove the protective film from the optical or electronic member. The surface protective film using the typical urethane-based adhesive in the adhesive layer leads to a problem of deterioration in reworkability due to increase in peel strength when attached to the optical or electronic member for a long time.

The background technique of the present invention is disclosed in Korean Patent Laid-open Publication No. 10-2012-0050136 and the like.

### SUMMARY

According to an aspect of one or more embodiments of the present invention, an adhesive film for surface protection that exhibits low variation in peel strength even after being left under high temperature/humidity conditions for a long time is provided.

According to another aspect of one or more embodiments of the present invention, an adhesive film for surface protection that has good appearance even after being left under high temperature/humidity conditions for a long time is provided.

According to another aspect of one or more embodiments of the present invention, an adhesive film for surface protection that can be attached to an adherend to protect the adherend and can be easily removed therefrom without deformation and/or damage of the adherend even after being left under high temperature/humidity conditions for a long time is provided.

One or more embodiments of the present invention relate to an adhesive film for surface protection.

According to one or more embodiments, an adhesive film for surface protection is formed of a composition for adhesive films including a curable component including a urethane-based binder, a curing agent, and a plasticizer, and the adhesive film has a peel strength variation rate of −50% to 20%, as calculated by the following Equation 1:

Peel strength variation rate=[(P2−P1)/P1]×100,

where P1 is an initial peel strength of the adhesive film with respect to an alkali-free glass plate (unit: gf/inch), and P2 is a peel strength of the adhesive film with respect to the alkali-free glass plate (unit: gf/inch) after the adhesive film is left at 85° C. and 85% RH (relative humidity) for 10 days.

In one or more embodiments, the adhesive film may have a P1 value of 4 gf/inch or less and a P2 value of 4 gf/inch or less.

In one or more embodiments, the plasticizer may be present in an amount of 5 parts by weight to 20 parts by weight relative to 100 parts by weight of the curable component.

In one or more embodiments, the plasticizer may include at least one selected from among an ester of a C₆ to C₁₈ monobasic or polybasic acid and a C₃ to C₁₈ branched alcohol, an ester of a C₁₄ to C₁₈ unsaturated fatty acid or branched chain acid and a tetravalent or lower alcohol, and an ester of a C₆ to C₁₀ monobasic or polybasic acid and a polyalkylene glycol.

In one or more embodiments, the plasticizer may be an ester-based compound having one or more ester groups represented by the following Formula 1:

*-C(═O)-—O—X—CH(CH₃)₂,

where * is a linking site of an element, and X is a single bond or a bivalent organic group.

In one or more embodiments, the plasticizer may include at least one selected from among isopropyl myristate, isopropyl palmitate, isotridecyl isononanoate, 1,2-cyclohexanedicarboxylic diisononyl ester, isostearyl palmitate, isostearyl laurate, diisostearyl adipate, and diisocetyl sebacate.

In one or more embodiments, the urethane-based binder may be a hyperbranched binder.

In one or more embodiments, the urethane-based binder may include at least one unit selected from among units derived from polyether-based polyols and polyester-based polyols.

In one or more embodiments, the urethane-based binder may be formed of at least one polyisocyanate compound and a polyol including 50 wt % to 95 wt % of a polyether-based triol and 5 wt % to 50 wt % of a polyether-based diol.

In one or more embodiments, the polyether-based diol may have a number average molecular weight of 400 to 10,000, and the polyether-based triol may have a number average molecular weight of 400 to 10,000.

In one or more embodiments, the urethane-based binder may be formed of at least one polyisocyanate compound and a polyol including 50 wt % to 90 wt % of a polyether-based triol, 5 wt % to 40 wt % of a polyether-based diol, and 5 wt % to 40 wt % of a polyester-based diol.

In one or more embodiments, the polyether-based diol may have a number average molecular weight of 400 to 10,000, the polyether-based triol may have a number average molecular weight of 400 to 10,000, and the polyester-based diol may have a number average molecular weight of 1,000 to 5,000.

In one or more embodiments, the curable component may further include a polyol.

In one or more embodiments, the polyol may be present in an amount of greater than 0 to 70 parts by weight relative to 100 parts by weight of the urethane-based binder.

In one or more embodiments, the polyol may include at least one selected from among a polyether-based polyol, a polyester-based polyol, a polycaprolactone-based polyol, and a polycarbonate-based polyol.

In one or more embodiments, the curing agent may include an isocyanate-based curing agent and may be present in an amount of 1 part by weight to 10 parts by weight relative to 100 parts by weight of the curable component.

In one or more embodiments, the curing agent may include an isocyanurate type isocyanate-based curing agent.

In one or more embodiments, the adhesive film may further include at least one selected from among a crosslinking catalyst, a leveling agent, an antistatic agent, an antioxidant, and a retarder.

One or more embodiments of the present invention relate to an optical member including an optical film and the adhesive film for surface protection according to the present invention on at least one surface of the optical film.

According to an aspect of one or more embodiments of the present invention, an adhesive film for surface protection exhibits low variation in peel strength even after being left under high temperature/humidity conditions for a long time.

According to another aspect of one or more embodiments of the present invention, an adhesive film for surface protection has good appearance even after being left under high temperature/humidity conditions for a long time.

According to another aspect of one or more embodiments of the present invention, an adhesive film for surface protection can be attached to an adherend to protect the adherend and can be easily removed therefrom without deformation and/or damage of the adherend even after being left under high temperature/humidity conditions for a long time.

### BRIEF DESCRIPTION OF THE DRAWING

The FIGURE is a cross-sectional view of a specimen for measurement of modulus of adhesive films for surface protection in examples.

### DETAILED DESCRIPTION

Herein, some embodiments of the present invention will be described in further detail. However, it is to be understood that the present invention is not limited to the following embodiments and may be embodied in different ways. The following embodiments are provided to provide a thorough understanding of the invention to those skilled in the art.

Herein, “adherend” may include a glass plate, a plastic film, or a panel for display devices, without being limited thereto. The “adherend” may represent an outermost surface of an optical member or an electronic member.

Herein, “peel strength” is a value measured upon separation of an adhesive film from an alkali-free glass plate provided as an adherend at a peeling rate of 2,400 mm/min and at a peeling angle of 180° under conditions of 23° C. and 50% RH (relative humidity) in accordance with JIS Z0237.

Herein, “modulus” refers to tensile modulus measured at 25° C. Specifically, “modulus” is measured using a specimen for measurement of modulus. For preparation of the specimen, a composition for adhesive films is coated to a predetermined thickness on a surface of a fluorinated film (FL-75BML, Dongwon Intec Co.), and a polyethylene terephthalate (PET) film is attached to the coating layer, followed by drying at 130° C. for 4 minutes and aging at 50° C. for 2 days, thereby forming a laminate in which a 75 μm thick adhesive protective film is interposed between the fluorinated film and the PET film. Then, the specimen is prepared by cutting the laminate into a dog bone shape as shown in the FIGURE, followed by removing the fluorinated film and the PET film from the laminate.

Referring to the FIGURE, the prepared specimen has a dog bone shape and has an overall length of 40 mm, an overall width of 15 mm, and a thickness of 75 μm. Modulus of the specimen can be measured using a modulus tester (Instron Corp.). Specifically, the left end of the dog bone-shaped specimen shown in the FIGURE is connected to a first jig of the modulus tester, and the right end of the specimen is connected to a second jig of the modulus tester. Here, a portion of the left end connected to the first jig has the same area as a portion of the right end connected to the second jig. Then, with the first jig secured in place, modulus of the specimen is measured by stretching the specimen on the second jig under conditions of load cell: 1 kN, tensile rate: 50 mm/min, and temperature: 25° C. until breakage of a portion of the dog bone-shaped specimen of the FIGURE, which is indicated by a length of 15 mm and a width of 5 mm.

Herein, “number average molecular weight” may be measured by any typical method known to those skilled in the art, or by referring to a commercially available catalog in the art. For example, the number average molecular weight may be obtained by gel permeation chromatography in accordance with polystyrene standards.

As used herein to represent a specific numerical range, “X to Y” means a value greater than or equal to X and less than or equal to Y (X and Y).

An adhesive film for surface protection is a processing film adhered to an adherend to temporarily protect the adherend and removed therefrom after a period of time (e.g., a predetermined period of time). The adhesive film protects the adherend when attached thereto and is removed therefrom without deformation of and/or damage to the adherend. To this end, it is desirable that the adhesive film have peel strength within a certain range (e.g., a predetermined range), but is not limited thereto.

In an embodiment, the adhesive film for surface protection may have a peel strength (initial peel strength) of 4 gf/inch or less, for example, greater than 0 gf/inch, 0.5 gf/inch, 1 gf/inch, 1.5 gf/inch, 2 gf/inch, 2.5 gf/inch, 3 gf/inch, 3.5 gf/inch, or 4 gf/inch, and, in an embodiment, greater than 0 gf/inch to 4 gf/inch, and, in an embodiment, 1 gf/inch to 4 gf/inch. Within this range, the adhesive film can protect an adherend and can be removed therefrom without deformation of and/or damage to the adherend.

The adhesive film for surface protection according to embodiments of the present invention exhibits low variation in peel strength even after being left under high temperature/humidity conditions for a long time. As a result, when attached again to the adherend after being left under high temperature/humidity conditions for a long time, the adhesive film can protect an adherend and can be removed therefrom without deformation of and/or damage to the adherend.

By contrast, a typical adhesive film for surface protection can suffer from surface contamination or poor appearance due to elution of a component, for example, a plasticizer, derived therefrom when left under high temperature/humidity conditions for a long time. Such contamination and poor appearance of the adhesive film can cause failure in protection of an adherend due to increase in variation of peel strength when the adhesive film is left under high temperature/humidity conditions for a long time. Further, after being attached to the adherend, the typical adhesive film for surface protection is subjected to assembly, inspection, processing, and transportation processes of a typical optical display. In such several processes, a laminate of the adhesive film and the adherend can be cut to a certain size (e.g., a predetermined size). Such contamination and poor appearance of the adhesive film can cause failure in a cutting process.

Even after being left under high temperature/humidity conditions for a long time, the adhesive film for surface protection according to embodiments of the present invention does not allow any elution of a component, particularly a plasticizer, therefrom to prevent or substantially prevent surface contamination of the adhesive film, thereby securing good appearance. Accordingly, the adhesive film according to the present invention can protect an adherend and does not cause failure in a cutting process even after being left under high temperature/humidity conditions for a long time.

Herein, an adhesive film for surface protection (herein, “adhesive film”) according to an embodiment of the present invention will be described.

The adhesive film according to an embodiment of the present invention has a peel strength variation rate of −50% to 20%, as calculated according to Equation 1. Within this range of peel strength variation rate, the adhesive film can protect an adherend and can be removed therefrom without deformation of and/or damage to the adherend, when attached again to the adherend after being left under high temperature/humidity conditions for a long time. For example, the adhesive film may have a peel strength variation rate of −50%, −49%, −48%, −47%, −46%, −45%, −44%, −43%, −42%, −41%, −40%, −39%, −38%, −37%, −36%, −35%, −34%, −33%, −32%, −31%, −30%, −29%, −28%, −27%, −26%, −25%, −24%, −23%, −22%, −21%, −20%, −19%, −18%, −17%, −16%, −15%, −14%, −13%, −12%, −11%, −10%, −9%, −8%, −7%, −6%, −5%, −4%, −3%, −2%, −1%, 0%, 1%, 2%, 3%, 4%, 5%, 6%, 7%, 8%, 9%, 10%, 11%, 12%, 13%, 14%, 15%, 16%, 17%, 18%, 19%, or 20%, and, in an embodiment, −30% to 20%, as calculated according to Equation 1:

Peel strength variation rate=[(P2−P1)/P1]×100, Equation 1

where P1 is initial peel strength of the adhesive film with respect to an alkali-free glass plate (unit: gf/inch), and P2 is peel strength of the adhesive film with respect to the alkali-free glass plate (unit: gf/inch) after the adhesive film is left at 85° C. and 85% RH for 10 days.

In an embodiment, the adhesive film may have a P1 value of 4 gf/inch or less, for example, greater than 0 gf/inch, 0.5 gf/inch, 1 gf/inch, 1.5 gf/inch, 2 gf/inch, 2.5 gf/inch, 3 gf/inch, 3.5 gf/inch, or 4 gf/inch, and, in an embodiment, greater than 0 gf/inch to 4 gf/inch, and, in an embodiment, 1 gf/inch to 4 gf/inch. Within this range, the adhesive film can protect an adherend and can be removed therefrom without deformation of and/or damage to the adherend.

In an embodiment, the adhesive film may have a P2 value of 4 gf/inch or less, for example, greater than 0 gf/inch, 0.5 gf/inch, 1 gf/inch, 1.5 gf/inch, 2 gf/inch, 2.5 gf/inch, 3 gf/inch, 3.5 gf/inch, or 4 gf/inch, and, in an embodiment, greater than 0 gf/inch to 4 gf/inch, and, in an embodiment, 1 gf/inch to 4 gf/inch, and, in an embodiment, 1.5 gf/inch to 4 gf/inch. Within this range, the adhesive film can protect an adherend and can be removed therefrom without deformation of and/or damage to the adherend.

The adhesive film according to the present invention may have a modulus of 0.05 MPa to 0.8 MPa at 25° C. Within this range, the adhesive film can exhibit good wettability with respect to an adherend to be attached thereto without bubble generation and/or delamination and can exhibit good scattering resistance to secure good cuttability and processability. For example, the adhesive film may have a modulus at 25° C. of 0.05 MPa, 0.1 MPa, 0.15 MPa, 0.2 MPa, 0.25 MPa, 0.3 MPa, 0.35 MPa, 0.4 MPa, 0.45 MPa, 0.5 MPa, 0.55 MPa, 0.6 MPa, 0.65 MPa, 0.7 MPa, 0.75 MPa, or 0.8 MPa, and, in an embodiment, 0.1 MPa to 0.8 MPa, and, in an embodiment, 0.5 MPa to 0.8 MPa.

The adhesive film according to the present invention may have a haze of 5% or less, for example, 0%, 1%, 2%, 3%, 4%, or 5%, and, in an embodiment, 0% to 1%, in the visible spectrum, for example, at a wavelength of 550 nm. Within this range, the adhesive film has good cuttability and processability upon cutting after being adhered to an adherend.

The adhesive film according to the present invention may have a thickness of 100 μm or less, for example, greater than 0 μm to 75 μm. Within this range, the adhesive film can protect an adherend and can be easily removed therefrom.

The adhesive film according to the present invention may be formed of a composition for adhesive films described below. In an embodiment, the adhesive film according to the present invention may include a cured product of the composition.

Next, a composition for adhesive films according to an embodiment of the present invention will be described.

The composition for adhesive films according to an embodiment includes 100 parts by weight of a curable component including a urethane-based binder; a curing agent; and 5 parts by weight to 20 parts by weight of a plasticizer.

### Curable component

The curable component is cured by the curing agent to form a matrix of the adhesive film. The curable component is cured by the curing agent to allow the adhesive film to reach a peel strength variation rate within the range of −50% to 20% according to Equation 1. Herein, the curable component means a component capable of being cured by the curing agent described below.

The curable component includes a urethane-based binder.

The urethane-based binder may have at least one urethane bond and at least one hydroxyl group (—OH). With at least one hydroxyl group, the urethane-based binder is cured by the curing agent to form the matrix of the adhesive film while providing peel strength.

The urethane-based binder may be present in an amount of 60 wt % to 100 wt %, for example, 60 wt %, 65 wt %, 70 wt %, 75 wt %, 80 wt %, 85 wt %, 90 wt %, 95 wt %, or 100 wt %, and, in an embodiment, 60 wt % to less than 100 wt %, and, in an embodiment, 60 wt % to 95 wt %, in the curable component in the composition for adhesive films. Within this range, the adhesive film can have sufficient peel strength.

The urethane-based binder may have a number average molecular weight of 30,000 to 150,000, for example, 30,000, 35,000, 40,000, 45,000, 50,000, 55,000, 60,000, 65,000, 70,000, 75,000, 80,000, 85,000, 90,000, 95,000, 100,000, 105,000, 110,000, 115,000, 120,000, 125,000, 130,000, 135,000, 140,000, 145,000, or 150,000, and, in an embodiment, 50,000 to 70,000. Within this range, the adhesive film can easily reach peel strength and modulus according to the present invention while securing good wettability.

The urethane-based binder may be prepared through reaction of at least one type of polyol and at least one polyisocyanate compound. The urethane-based binder may be a random copolymer having a unit derived from the polyol.

The polyol may include at least one selected from among a polyether-based polyol, a polyester-based polyol, a polyacrylic-based polyol, a polycaprolactone-based polyol, and a polycarbonate-based polyol. In an embodiment, the polyol includes at least one polyether-based polyol and further include at least one polyester-based polyol.

The urethane-based binder may include a unit derived from the polyether-based polyol. The urethane-based binder may further include a unit derived from the polyester-based polyol.

The polyether-based polyol has an alkylene oxide group and, in an embodiment, is a polyether-based polyol having at least two hydroxyl groups, for example, a bifunctional polyether polyol (polyether-based diol) or a trifunctional polyether polyol (polyether-based trial), such as polyethylene glycol, polypropylene glycol, polytetramethylene glycol, and the like, a trifunctional polyether-based polyol (polyether-based trial) of a glycerin alkylene oxide adduct, and the like. The urethane-based binder may become a hyperbranched binder to have a better organized structure than a linear structure, thereby enabling easier implementation of the effects of the invention. Here, “hyperbranched” means a polymer having a dendritic branched structure having many terminal groups.

At least one or two types of polyether-based polyols may be used in preparation of the urethane binder.

The polyether-based polyol may have a number average molecular weight of 400 to 10,000, for example, 400, 500, 1,000, 1,500, 2,000, 2,500, 3,000, 3,500, 4,000, 4,500, 5,000, 5,500, 6,000, 6,500, 7,000, 7,500, 8,000, 8,500, 9,000, 9,500, or 10,000, and, in an embodiment, 1,000 to 7,000. Within this range, the adhesive film can easily reach peel strength and modulus according to the present invention while securing good wettability.

In preparation of the urethane-based binder, the polyether-based polyol may be present in an amount of 50 wt % to 100 wt %, for example, 50 wt %, 55 wt %, 60 wt %, 65 wt %, 70 wt %, 75 wt %, 80 wt %, 85 wt %, 90 wt %, 95 wt %, or 100 wt %, and, in an embodiment, 50 wt % to 99 wt %, based on the total amount of the polyols for the preparation of the urethane-based binder. Within this range, the adhesive film can easily realize the effects of the present invention.

In an embodiment, the polyether-based polyol includes a mixture of a polyether-based diol and a polyether-based trial to easily realize the effects of the present invention.

For example, in preparation of the urethane-based binder, the polyether-based trial may be present in an amount of 50 wt % to 95 wt %, for example, 50 wt %, 55 wt %, 60 wt %, 65 wt %, 70 wt %, 75 wt %, 80 wt %, 85 wt %, 90 wt %, or 95 wt %, and, in an embodiment, 50 wt % to 90 wt %, based on the total amount of the polyols for the preparation of the urethane-based binder, and the polyether-based diol may be present in an amount of 5 wt % to 50 wt %, for example, 5 wt %, 10 wt %, 15 wt %, 20 wt %, 25 wt %, 30 wt %, 35 wt %, 40 wt %, 45 wt %, or 50 wt %, and, in an embodiment, 5 wt % to 40 wt %, and, in an embodiment, 10 wt % to 50 wt %, based on the total amount of the polyols for the preparation of the urethane-based binder. Within this range, the adhesive film can easily realize the effects of the present invention.

In an embodiment, the polyether-based diol may have a number average molecular weight of 400 to 10,000, for example, 400, 500, 1,000, 1,500, 2,000, 2,500, 3,000, 3,500, 4,000, 4,500, 5,000, 5,500, 6,000, 6,500, 7,000, 7,500, 8,000, 8,500, 9,000, 9,500, or 10,000, and, in an embodiment, 1,000 to 6,000. Within this range, the adhesive film can easily reach peel strength and modulus according to the present invention while securing good wettability.

In an embodiment, the polyether-based triol may have a number average molecular weight of 400 to 10,000, for example, 400, 500, 1,000, 1,500, 2,000, 2,500, 3,000, 3,500, 4,000, 4,500, 5,000, 5,500, 6,000, 6,500, 7,000, 7,500, 8,000, 8,500, 9,000, 9,500, or 10,000, and, in an embodiment, 2,000 to 8,000. Within this range, the adhesive film can easily reach peel strength and modulus according to the present invention while securing good wettability.

In an embodiment, the urethane-based binder may be produced from at least one polyisocyanate compound and a polyol including 50 wt % to 95 wt % of the polyether-based triol and 5 wt % to 50 wt % of the polyether based diol. Within this range, the adhesive film can easily realize the effects of the present invention.

The polyester-based polyol may include a polyol obtained through esterification between at least one type of polyol and at least one type of acidic component.

Here, the polyol may include at least one selected from among ethylene glycol, propylene glycol, diethylene glycol, 1,3-butanediol, 1,4-butanediol, neopentyl glycol, 3-methyl-1,5-pentanediol, 2-butyl-2-ethyl-1,3-propanediol, 2,4-diethyl-1,5-pentanediol, 1,2-hexanediol, 1,6-hexanediol, 2-ethyl-1,3-hexanediol, 1,8-octanediol, 1,9-nonanediol, 2-methyl-1,8-octanediol, 1,8-decanediol, octadecanediol, glycerin, trimethylolpropane, pentaerythritol, and hexanetriol, without being limited thereto. The acidic component may be succinic acid, methyl succinic acid, adipic acid, azelaic acid, sebacic acid, 1,12-dodecanedioic acid, 1,14-tetradecanedioic acid, dimer acid, 2-methyl-1,4-cyclohexane dicarboxylic acid, 2-ethyl-1,4-cyclohexane dicarboxylic acid, terephthalic acid, isophthalic acid, phthalic acid, 1,4-naphthalene dicarboxylic acid, 4,4′-biphenyl dicarboxylic acid, or acid anhydrides thereof, without being limited thereto.

In preparation of the urethane-based binder, one or two types of polyester-based polyols may be used.

The polyester-based polyol, for example, a polyester-based diol, may have a number average molecular weight of 1,000 to 5,000, for example, 1,000, 1,500, 2,000, 2,500, 3,000, 3,500, 4,000, 4,500, or 5,000, and, in an embodiment, 2,000 to 3,000. Within this range, the adhesive film can easily reach peel strength and modulus according to the present invention.

In preparation of the urethane-based binder, the polyester-based polyol may be optionally present in an amount of 0 wt % to 50 wt %, for example, 0 wt %, greater than 0 wt %, 1 wt %, 5 wt %, 10 wt %, 15 wt %, 20 wt %, 25 wt %, 30 wt %, 35 wt %, 40 wt %, 45 wt %, or 50 wt %, and, in an embodiment, 1 wt % to 50 wt %, and, in an embodiment, 5 wt % to 40 wt %, based on the total amount of the polyols for the preparation of the urethane-based binder. Within this range, the adhesive film can easily realize the effects of the present invention.

The polyester-based polyol may include a polyester-based polyol having at least two hydroxyl groups, for example, a bifunctional polyester-based polyol (polyester-based diol) or a trifunctional polyester-based polyol (polyester-based triol).

As a result, the urethane-based binder becomes a hyperbranched binder, thereby enabling easy implementation of the effects of the present invention. In an embodiment, a polyester-based diol is used as the polyester-based polyol.

In an embodiment, the urethane-based binder may be prepared from at least one polyisocyanate compound and a polyol including 50 wt % to 90 wt % of the polyether-based triol, 5 wt % to 40 wt % of the polyether-based diol, and 5 wt % to 40 wt % of the polyester-based diol. Within this range, the adhesive film can easily realize the effects of the present invention.

The polyisocyanate compound may include a polyisocyanate compound including a plurality of isocyanate groups (-NCO). The polyisocyanate compound may be selected from typical polyisocyanate compounds known in the art and may include at least one selected from among an aliphatic polyisocyanate, an alicyclic polyisocyanate, an aromatic polyisocyanate, and an aromatic alicyclic polyisocyanate. In an embodiment, an aliphatic polyisocyanate is used.

The aliphatic polyisocyanate compound may include at least one selected from among hexamethylene diisocyanate, trimethylene diisocyanate, tetramethylene diisocyanate, pentamethylene diisocyanate, 1,2-propylene diisocyanate, 2,3-butylene diisocyanate, 1,3-butylene diisocyanate, dodecamethylene diisocyanate, 2,4,4-trimethylhexamethylene diisocyanate, without being limited thereto.

The polyisocyanate compound may be present in an amount of 1 part by weight to 10 parts by weight, for example 1, 2, 3, 4, 5, 6, 7, 8, 9, or 10 parts by weight, and, in an embodiment, 1 part by weight to 5 parts by weight, relative to 100 parts by weight of all polyols. Within this range, the urethane-based binder according to the present invention can be easily prepared.

Reaction may be performed at a certain temperature (e.g., a predetermined temperature) after adding a catalyst to a mixture including at least one type of polyol and at least one type of polyisocyanate compound.

The catalyst may be a tin compound including dibutyl tin dilaurate (DBTDL) and sodium 2-ethyl hexanoic acid, without being limited thereto.

The urethane-based binder may be prepared by heating the polyol mixture in a reactor at 80° C. to 100° C. for 10 minutes to 30 minutes under a nitrogen atmosphere until moisture is completely removed from the reactor, reducing the interior temperature of the reactor to 65° C. to 70° C., adding a polyisocyanate compound and a catalyst to the reactor, followed by primary polymerization at 65° C. to 75° C. for 3 hours to 4 hours and secondary polymerization at 75° C. to 85° C. for 60 minutes to 120 minutes.

In an embodiment, the urethane-based binder may be a (meth)acrylate-free urethane-based binder that does not contain a (meth)acrylate group.

The curable component may further include a polyol.

The polyol has at least one hydroxyl group to further reduce the peel strength variation rate.

The polyol may further include at least one selected from among a polyether-based polyol, a polyester-based polyol, a polycaprolactone-based polyol, and a polycarbonate-based polyol. In an embodiment, the polyol is a polyether-based polyol.

The polyether-based polyol has an alkylene oxide group and, in an embodiment, is a polyether based polyol having at least two hydroxyl groups, for example, a bifunctional polyether-based polyol (polyether-based diol) or a trifunctional polyether-based polyol (polyether-based triol), such as polyethylene glycol, polypropylene glycol, polytetramethylene glycol, and the like, a trifunctional polyether-based polyol (polyether-based triol) of a glycerin alkylene oxide adduct, and the like.

The polyester-based polyol may include a polyol obtained through esterification between at least one type of polyol and at least one type of acidic component. Here, the polyol and the acidic component may be the same as those described above.

The polyol may have a number average molecular weight of 400 to 10,000, for example, 400, 500, 1,000, 1,500, 2,000, 2,500, 3,000, 3,500, 4,000, 4,500, 5,000, 5,500, 6,000, 6,500, 7,000, 7,500, 8,000, 8,500, 9,000, 9,500, or 10,000, and, in an embodiment, 1,000 to 7,000. Within this range, the adhesive film can easily reach peel strength and modulus according to the present invention while securing good wettability.

In the curable component, the polyol may be present in an amount of 0 wt % to 50 wt %, for example, 0 wt % or more, greater than 0 wt %, 1 wt %, 5 wt %, 10 wt %, 15 wt %, 20 wt %, 25 wt %, 30 wt %, 35 wt %, 40 wt %, 45 wt %, or 50 wt %, for example, 0 wt % to less than 40 wt %, and, in an embodiment, 5 wt % to 40 wt %. Within this range, the adhesive film can secure inherent effects of the polyol.

The polyol may be present in an amount of 0 to 70 parts by weight, for example, 0 parts by weight or more, greater than 0 parts by weight, 1, 5, 10, 15, 20, 25, 30, 35, 40, 45, 50, 55, 60, 65, or 70 parts by weight, and, in an embodiment, greater than 0 to 70 parts by weight, and, in an embodiment, 15 parts by weight to 70 parts by weight, relative to 100 parts by weight of the urethane-based binder. Within this range, the adhesive film can secure inherent effects of the polyol.

### Curing Agent

The curing agent can cure the curable component to provide peel strength to the adhesive film. In an embodiment, the curing agent may be a heat curable agent.

With at least one isocyanate group (-NCO), the curing agent can react with the hydroxyl groups in the urethane-based binder and/or the polyol to provide a matrix of the adhesive film while providing peel strength to the adhesive film.

The isocyanate-based curing agent is a multifunctional isocyanate-based curing agent having a plurality of isocyanate groups and may include a typical isocyanate-based curing agent known to those skilled in the art.

In an embodiment, the isocyanate-based curing agent may include at least one selected from among an aliphatic isocyanate compound, an alicyclic isocyanate compound, an aromatic isocyanate compound, and an aromatic aliphatic isocyanate compound, polyol adducts thereof, biurets thereof, or isocyanurates thereof. For example, the aliphatic isocyanate compound may include at least one selected from among hexamethylene diisocyanate, trimethylene diisocyanate, tetramethylene diisocyanate, pentamethylene diisocyanate, 1,2-propylene diisocyanate, 2,3-butylene diisocyanate, 1,3-butylene diisocyanate, dodecamethylene diisocyanate isocyanate, and 2,4,4-trimethylhexamethylene diisocyanate, without being limited thereto. For example, the aromatic isocyanate compound may include at least one selected from among toluene diisocyanate, xylylene diisocyanate, and phenylene diisocyanate, without being limited thereto.

In an embodiment, the isocyanate-based curing agent includes an isocyanurate of the isocyanate-based curing agent. The isocyanurate curing agent allows easy implementation of the effects of the present invention in combination with a composition including the urethane-based binder and the plasticizer according to the present invention.

In an embodiment, the isocyanate-based curing agent may be present in an amount of 80 parts by weight or more, for example, 90 parts by weight to 100 parts by weight, relative to 100 parts by weight of all of the curing agent in the composition.

The curing agent may be present in an amount of 1 part by weight to 10 parts by weight, for example, 1, 2, 3, 4, 5, 6, 7, 8, 9, or 10 parts by weight, and, in an embodiment, 2 parts by weight to 6 parts by weight, relative to 100 parts by weight of the curable component. Within this range, the curing agent can assist in formation of an adhesive film having the effects of the present invention.

### Plasticizer

The plasticizer can secure scattering resistance in a cutting process by suppressing increase in modulus of the adhesive film. Here, “scattering resistance” means that scattering particles are not generated upon cutting the adhesive film or a laminate of the adhesive film and an adherend.

The plasticizer may be present in an amount of 5 parts by weight to 20 parts by weight relative to 100 parts by weight of the curable component. Within this range, the plasticizer can assist in achieving a peel strength variation rate of −50% to 20% and can prevent or substantially prevent elution thereof even after the adhesive film is left under high temperature/humidity conditions for a long time. For example, the plasticizer may be present in an amount of 5, 6, 7, 8, 9, 10, 11, 12, 13, 14, 15, 16, 17, 18, 19, or 20 parts by weight, and, in an embodiment, 10 parts by weight to 20 parts by weight, relative to 100 parts by weight of the curable component.

The plasticizer may be an ester-based plasticizer and may include any of an ester of a C₆ to C₁₈ monobasic or polybasic acid and a C₃ to C₁₈ branched alcohol, an ester of a C₁₄ to C₁₈ unsaturated fatty acid or branched chain acid and a tetravalent or lower alcohol, and an ester of a C₆ to C₁₀ monobasic or polybasic acid and a polyalkylene glycol.

In an embodiment, the plasticizer may have one or more ester groups represented by the following Formula 1. As the ester group has a branched terminal CH(CH₃)₂, as shown in Formula 1, the adhesive film can protect an adherend while reducing the peel strength variation rate even after being left under high temperature/humidity conditions for a long time.

*-C(═O)—O—X—CH(CH₃)₂, Formula 1

where * is a linking site of an element, and X is a single bond or a bivalent organic group.

In an embodiment, X is a single bond or a linear or branched C₆ to C₂₀ alkylene group.

In an embodiment, the plasticizer may have one or more ester groups represented by the following Formula 2. As the ester group has a branched terminal CH(CH₃)₂, as shown in Formula 2, the adhesive film can protect an adherend while reducing the peel strength variation rate even after being left under high temperature/humidity conditions for a long time.

*-C(═O)—O—X₁—CH₂—CH(CH₃)₂, Formula 2

where * is a linking site of an element, and X₁ is a single bond or a linear bivalent organic group.

In an embodiment, X₁ is a single bond or a linear C₆ to C₂₀ alkylene group.

For example, the plasticizer may include at least one selected from among isopropyl myristate, isopropyl palmitate, isotridecyl isononanoate, 1,2-cyclohexane dicarboxylic diisononyl ester, isostearyl palmitate, isostearyl laurate, diisostearyl adipate, and diisocetyl sebacate, without being limited thereto.

The plasticizer, the ester of Formula 1, the ester of Formula 2, or the at least one selected from among isopropyl myristate, isopropyl palmitate, isotridecyl isononanoate, 1,2-cyclohexane dicarboxylic diisononyl ester, isostearyl palmitate, isostearyl laurate, diisostearyl adipate, and diisocetyl sebacate may be present in an amount of 80 parts by weight or more, and, in an embodiment, 90 parts by weight to 100 parts by weight, relative to 100 parts by weight of all plasticizers in the adhesive film or the composition for adhesive films.

The adhesive film may further include at least one selected from among a crosslinking catalyst, a leveling agent, an antistatic agent, an antioxidant, and a retarder.

The crosslinking catalyst can promote reaction between the curable component and the curing agent.

The crosslinking catalyst may at least one metal-based catalyst. The metal-based catalyst may include a tin-based catalyst and/or a non-tin-based catalyst. Each of the tin-based catalyst and the non-tin-based catalyst may be selected from typical kinds well-known to those skilled in the art. For example, the tin-based catalyst may include any of dibutyl tin dichloride, dibutyl tin oxide, dibutyl tin dilaurate, dibutyl tin sulfide, dibutyl tin diacetate, and dibutyl tin maleate, without being limited thereto.

The crosslinking catalyst may be present in an amount of 0.005 parts by weight to 0.5 parts by weight, and, in an embodiment, 0.005 parts by weight to 0.1 parts by weight, relative to 100 parts by weight of the curable component. Within this range, the crosslinking catalyst can secure satisfactory pot life and rapid curing.

The leveling agent may enhance leveling properties of the adhesive film. The leveling agent may include any of an acrylic based leveling agent, a fluorine based leveling agent, a silicone based leveling agent, and a silicone-acrylate based leveling agent.

The leveling agent may be present in an amount of 0.1 parts by weight to 5 parts by weight, and, in an embodiment, 0.1 parts by weight to 1 part by weight, relative to 100 parts by weight of the curable component. Within this range, the adhesive film can provide low initial peel strength.

The antistatic agent can prevent or substantially prevent damage to an adherend by suppressing generation of static electricity in the course of removing the adhesive film from the adherend after attaching the adhesive film thereto. The antistatic agent may include a typical antistatic agent well-known to those skilled in the art. For example, the antistatic agent may include an ionic liquid.

The antistatic agent may be present in an amount of 0.01 parts by weight to 5 parts by weight, and, in an embodiment, 0.01 parts by weight to 1 part by weight, relative to 100 parts by weight of the curable component. Within this range, the antistatic agent can secure inherent properties thereof without affecting various properties of the adhesive film.

The antioxidant can secure peel strength by blocking the adhesive film from an external environment to suppress release of the adhesive film. The antioxidant may include a typical antioxidant well-known to those skilled in the art. For example, the antioxidant may include any of cinnamate, phenol, sulfur, phosphorus, and HALS-based antioxidants.

The antioxidant may be present in an amount of 0.01 parts by weight to 5 parts by weight, and, in an embodiment, 0.01 parts by weight to 1 part by weight, relative to 100 parts by weight of the curable component. Within this range, the antioxidant can secure inherent properties thereof without affecting various properties of the adhesive film.

The retarder may include a typical retarder well-known to those skilled in the art. For example, the retarder may include acetyl acetone or complexes thereof.

The retarder may be present in an amount of 0.01 parts by weight to 5 parts by weight, and, in an embodiment, 0.01 parts by weight to 3 parts by weight, relative to 100 parts by weight of the curable component. Within this range, the retarder can secure inherent properties thereof without affecting various properties of the adhesive film.

The composition for adhesive films may further include additives. The additives may include UV absorbents, UV stabilizers, heat stabilizers, surfactants, fillers, and pigments, without being limited thereto.

The adhesive film may be manufactured by coating the composition for adhesive films to a certain thickness (e.g., a predetermined thickness) on a base film and drying the composition at 110° C. to 140° C., followed by leaving the composition at 30° C. to 70° C. for 1 day to 3 days, without being limited thereto.

An optical member according to an embodiment of the invention includes an optical film and an adhesive film for surface protection formed on a surface of the optical film, in which the adhesive film for surface protection includes the adhesive film for surface protection according to an embodiment of the present invention.

The optical film may include a polyimide film as a display panel. In an embodiment, the optical film may be composed of a light emitting diode layer and a polyimide layer formed on at least one surface of the light emitting diode layer. An organic insulating layer or an inorganic insulating layer may be further formed between the optical film and a silicone-based adhesive protective film. The optical member may further include a release film (liner) on the other surface of the adhesive protective film. The release film can prevent or substantially prevent contamination of the adhesive protective film by foreign matter. The release film may be formed of the same material as or a different material from the optical film. For example, the release film may be formed of at least one resin selected from among a polyethylene terephthalate resin, a polycarbonate resin, a polyimide resin, a poly(meth)acrylate resin, a cyclic olefin polymer resin, and an acrylic resin. The release film may have a thickness of 10 μm to 100 μm, and, in an embodiment, 10 μm to 50 μm. Within this range, the release film can support the adhesive protective film.

Next, the present invention will be described in further detail with reference to some examples. However, these examples are provided for illustration and should not be construed in any way as limiting the present invention.

### EXAMPLE 1

100 parts by weight of a polyol including 70 parts by weight of PPG-3020, 15 parts by weight of PPG-6000, and 15 parts by weight of P-2010 was placed in a 1,000 mL jacket reactor under nitrogen purging conditions. Then, toluene was further added thereto to prepare a mixture, which in turn was stirred for 10 minutes and heated to 85° C. for 30 minutes under nitrogen purging conditions to remove remaining moisture. Next, the internal temperature of the reactor was reduced to 60° C., and 4 parts by weight of hexamethylene diisocyanate was added to the mixture. The mixture was further stirred at 60° C. for 10 minutes, and dibutyl tin dilaurate (DBTDL) as a catalyst was added. After 1 hour, the internal temperature of the reactor was increased to 70° C., followed by performing polymerization reaction for 6 hours. Then, the resulting urethane-based binder solution was diluted with toluene to prepare a solution with a solid content of 65 wt %, which in turn was cooled to room temperature to prepare a solid compound. The solid compound contains a urethane binder TOH-12.

A composition for adhesive films was prepared by mixing 100 parts by weight of the urethane-based binder TOH-12, 4.8 parts by weight of an isocyanate-based curing agent (Coronate HX), 0.4 parts by weight of a leveling agent (BYK-SILCLEAN 3700, BYK), 15 parts by weight of a plasticizer (isopropyl myristate), 0.25 parts by weight of an antistatic agent (FC-4400), 0.25 parts by weight of an antioxidant (Irganox 1010), 0.01 parts by weight of a crosslinking catalyst (Catalyst S, DBTDL), and 1.5 parts by weight of a retarder (acetyl acetone) in terms of solid content, followed by adding methyl ethyl ketone to the mixture.

The prepared composition was deposited to a predetermined thickness on an upper surface of a release film (PET film, thickness: 75 μm, TU73A, SKC) using an applicator and dried at 130° C. for 4 minutes. Then, with a release film (PET film with an antistatic coating layer formed thereon, thickness: 25 μm) placed on the composition layer, the resultant was left at 50° C. for 2 days, thereby fabricating an adhesive sheet including a laminate of the base film, the adhesive film (thickness: 75 μm) and the release film.

### EXAMPLE 2

A composition for adhesive films and an adhesive sheet were prepared in the same manner as in Example 1 except that the kind and/or the content of each of components of the composition for adhesive films were changed as listed in Table 1. In Table 1, “−” means that a corresponding component is not present, and parts by weight is provided as unit.

### EXAMPLES 3 AND 4

A composition for adhesive films and an adhesive sheet were prepared in the same manner as in Example 1 except that 85 parts by weight of the prepared urethane-based binder TOH-12 and 15 parts by weight of PPG-7000 as a polyol were mixed in terms of solid content and the kind and/or the content of each of components of the composition for adhesive films were changed as listed in Table 1.

### EXAMPLE 5

A composition for adhesive films and an adhesive sheet were prepared in the same manner as in Example 1 except that 60 parts by weight of a urethane-based binder SH101 and 40 parts by weight of PPG-7000 as a polyol were mixed in terms of solid content and the kind and/or the content of each of components of the composition for adhesive films were changed as listed in Table 1.

### Comparative Example 1

A composition for adhesive films and an adhesive sheet were prepared in the same manner as in Example 1 except that 60 parts by weight of a urethane-based binder SH101 and 40 parts by weight of PPG-7000 as a polyol were mixed in terms of solid content and the kind and/or the content of each of components of the composition for adhesive films were changed as listed in Table 1.

### Comparative Example 2

A composition for adhesive films and an adhesive sheet were prepared in the same manner as in Example 1 except that 60 parts by weight of a urethane-based binder TOH-12 and 40 parts by weight of PPG-7000 as a polyol were mixed in terms of solid content and the kind and/or the content of each of components of the composition for adhesive films were changed as listed in Table 1.

### Comparative Example 3

A composition for adhesive films and an adhesive sheet were prepared in the same manner as in Example 1 except that the kind and/or the content of each of components of the composition for adhesive films were changed as listed in Table 1. In Table 1, “−” means that a corresponding component is not present, and parts by weight is provided as unit.

Details of the components of the compositions for adhesive films prepared in the Examples and Comparative Examples are shown in Table 1.

TABLE 1

| | | Example | | | | | Comparative Example | | |
|---|---|---|---|---|---|---|---|---|---|
| | | 1 | 2 | 3 | 4 | 5 | 1 | 2 | 3 |
| Urethane- | TOH-12 | 100 | 100 | 85 | 85 | — | — | 60 | 100 |
| based | SH101 | — | — | — | — | 60 | 60 | — | — |
| binder | | | | | | | | | |
| Polyol | PPG- | — | — | 15 | 15 | 40 | 40 | 40 | — |
| | 7000 | | | | | | | | |
| Curing | Coronate | 4.8 | 4.1 | 3.8 | 3.8 | 4.5 | 4.5 | 4 | 4.8 |
| agent | HX | | | | | | | | |
| Leveling | BYK- | 0.4 | 0.5 | 0.3 | 0.3 | 0.3 | 0.3 | 0.3 | 0.3 |
| agent | SILCLEAN | | | | | | | | |
| | 3700 | | | | | | | | |
| Plasticizer | IPM | 15 | — | 10 | — | — | — | — | 50 |
| | EHP | — | — | — | — | — | 15 | 15 | — |
| | KAK139 | — | — | — | — | 15 | — | — | — |
| | DINCH | — | 10 | — | 10 | — | — | — | — |
| Antistatic | FC- | 0.25 | 0.25 | 0.25 | 0.25 | 0.25 | 0.25 | 0.25 | 0.25 |
| agent | 4400 | | | | | | | | |
| Antioxidant | Irganox | 0.25 | 0.25 | 0.25 | 0.25 | 0.25 | 0.25 | 0.25 | 0.25 |
| | 1010 | | | | | | | | |
| Crosslinking | Catalyst | 0.01 | 0.01 | 0.01 | 0.01 | 0.01 | 0.01 | 0.01 | 0.01 |
| catalyst | S | | | | | | | | |
| Retarder | Acetyl | 1.5 | 1.5 | 1.5 | 1.5 | 1.5 | 1.5 | 1.5 | 1.5 |
| | acetone | | | | | | | | |

Table 2 shows components used in the Examples and Comparative Examples.

TABLE 2

| | | | Number |
|---|---|---|---|
| | | | average |
| | | Solid | molecular |
| | Manufacturer | content | weight |
| PPG-3020 (polyether-based | Kumho | 100% | 3,000 |
| triol) | Petrochemical | | |
| PPG-6000 (polyether-based | Kumho | 100% | 6,000 |
| diol) | Petrochemical | | |
| PPG-7000 (polyether-based | Kumho | 100% | 7,000 |
| diol) | Petrochemical | | |
| P-2010 (polyester-based diol) | Kuraray | 100% | 3,000 |
| Hexamethylene diisocyanate | Tokyo Chemical | 100% | — |
| Coronate HX (isocyanurate | TOSOH | 100% | — |
| type) | | | |
| BYK-SILCLEAN 3700 | BYK | 25% | — |
| IPM (isopropyl myristate) | BASF | 100% | — |
| EHP (2-ethylhexyl palmitate) | KOKYU | 100% | — |
| | ALCOHOL | | |
| | KOGYO | | |
| KAK139 (isotridecyl | KOKYU | 100% | — |
| isononanoate) | ALCOHOL | | |
| | KOGYO | | |
| DINCH (1,2-cyclohexane | BASF | 100% | — |
| dicarboxylic diisononyl ester) | | | |
| SH101 (urethane-based | TOYO | 65% | — |
| binder) | | | |
| FC-4400 | 3M | 55% | — |
| Irganox 1010 | BASF | 100% | — |
| Catalyst S | — | 100% | — |
| Acetyl acetone | Daejung Chemical | 100% | — |

The compositions for adhesive films and/or the adhesive films for surface protective films prepared in the Examples and Comparative Examples were evaluated as to the following properties and results are shown in Table 3.

(1) Initial peel strength (unit: gf/inch): Each of the adhesive sheets prepared in the Examples and Comparative Examples was cut to a size of 200 mm×25 mm (length×width), and the adhesive film was exposed by removing the PET release film from the adhesive sheet. Then, an alkali-free glass plate was attached to an exposed surface of the adhesive film and was pressed once by a 2 kg roller, thereby obtaining a specimen having a laminate of the glass plate, the adhesive film, and the base film. Initial peel strength was measured in accordance with JIS Z0237.

30 minutes after preparation of the specimen, peel strength of the adhesive film with respect to the glass plate was measured under conditions of a peeling rate of 2,400 mm/min, a peeling angle of 180°, and a temperature of 23° C. and 50% RH (relative humidity) using a texture analyzer (TA Industry) as an apparatus for measuring the peel strength. Here, peel strength was measured three times, followed by calculation of an average of the measured values.

(2) Appearance (bubble generation): Bubble generation was checked on an exposed surface of the adhesive film after removing the PET release film from each of the adhesive sheets prepared in the Examples and Comparative Examples. No generation of bubbles was rated as OK, and slight or severe generation of bubbles was rated as NG.

(3) Peel strength variation rate (unit: %): Each of the adhesive sheets prepared in the Examples and Comparative Examples was cut to a size of 200 mm×25 mm (length×width) and the adhesive film was exposed by removing the PET release film from the adhesive sheet. A laminate of the adhesive film and the base film was left at 85° C. and 85% RH for 10 days. Then, an alkali-free glass plate was attached to an exposed surface of the adhesive film and was pressed once by a 2 kg roller, thereby obtaining a specimen including a laminate of the glass plate, the adhesive film, and the base film.

Peel strength was measured by the same method as in (1), followed by calculating a peel strength variation rate in accordance with Equation 1.

(4) Appearance after testing under high temperature/humidity conditions (elution of plasticizer): A laminate of the release film/adhesive film/release film prepared in each of the Examples and Comparative Examples was left at 85° C. and 85% RH for 10 days. Elution of the plasticizer was checked on the surface of the adhesive film. Elution of the plasticizer was checked with the naked eye. A specimen having a clean surface of the adhesive film due to no elution of the plasticizer was rated as OK, and a specimen having an unclean surface of the adhesive film due to elution of the plasticizer was rated as NG.

TABLE 3

| | Example | | | | | Comparative Example | | |
|---|---|---|---|---|---|---|---|---|
| | 1 | 2 | 3 | 4 | 5 | 1 | 2 | 3 |
| Initial peel | 2.4 | 3.2 | 1.5 | 2.6 | 1.6 | 2.9 | 3 | 3.2 |
| strength | | | | | | | | |
| Appearance | OK | OK | OK | OK | OK | OK | OK | NG |
| Peel strength | −23 | −26 | −11 | −2 | 19 | −58 | −66 | −78 |
| variation rate | | | | | | | | |
| Appearance | OK | OK | OK | OK | OK | NG | NG | NG |
| after high | | | | | | | | |
| temperature/ | | | | | | | | |
| humidity | | | | | | | | |
| conditions | | | | | | | | |

As shown in Table 3, the adhesive films for surface protective films according to the present invention had an initial peel strength of 4 gf/inch or less.

Accordingly, the adhesive film according to the present invention can protect an adherend and can be removed therefrom without deformation of and/or damage to the adherend. In addition, since the adhesive film according to the present invention exhibits low variation in peel strength even after being left under high temperature/humidity conditions for a long time, the adhesive film according to the present invention can be attached to an adherend to protect the adherend and can be easily removed therefrom without deformation of and/or damage to the adherend even after being left under high temperature/humidity conditions for a long time. Further, the adhesive film according to the present invention has good appearance and prevents or substantially prevents failure upon cutting a laminate of the adhesive film and an adherend, even after being left under high temperature/humidity conditions for a long time.

By contrast, the adhesive films of the Comparative Examples failed to realize all of the effects of the present invention.

While some embodiments have been described herein, it is to be understood that various modifications, changes, alterations, and equivalent embodiments can be made by those skilled in the art without departing from the spirit and scope of the present invention.

What is claimed is:

1. An adhesive film for surface protection formed of a composition for adhesive films comprising a curable component including a urethane-based binder, a curing agent, and a plasticizer, the adhesive film having a peel strength variation rate of −50% to 20%, as calculated by the following Equation 1:
Peel strength variation rate=[(P2−P1)/P1]×100,
where P1 is an initial peel strength of the adhesive film with respect to an alkali-free glass plate (unit: gf/inch), and P2 is a peel strength of the adhesive film with respect to the alkali-free glass plate (unit: gf/inch) after the adhesive film is left at 85° C. and 85% RH for 10 days.

2. The adhesive film for surface protection according to claim 1, wherein P1 is 4 gf/inch or less, and P2 is 4 gf/inch or less.

3. The adhesive film for surface protection according to claim 1, wherein the plasticizer is present in an amount of 5 parts by weight to 20 parts by weight relative to 100 parts by weight of the curable component.

4. The adhesive film for surface protection according to claim 1, wherein the plasticizer comprises at least one selected from among an ester of a C₆ to C₁₈ monobasic or polybasic acid and a C₃ to C₁₈ branched alcohol, an ester of a C₁₄ to C₁₈ unsaturated fatty acid or branched chain acid and a tetravalent or lower alcohol, and an ester of a C₆ to C₁₀ monobasic or polybasic acid and a polyalkylene glycol.

5. The adhesive film for surface protection according to claim 1, wherein the plasticizer is an ester-based compound having one or more ester groups represented by the following Formula 1:
*-C(═O)—O—X—CH(CH₃)₂,
where * is a linking site of an element, and X is a single bond or a bivalent organic group.

6. The adhesive film for surface protection according to claim 1, wherein the plasticizer comprises at least one selected from among isopropyl myristate, isopropyl palmitate, isotridecyl isononanoate, 1,2-cyclohexanedicarboxylic diisononyl ester, isostearyl palmitate, isostearyl laurate, diisostearyl adipate, and diisocetyl sebacate.

7. The adhesive film for surface protection according to claim 1, wherein the urethane-based binder is a hyperbranched binder.

8. The adhesive film for surface protection according to claim 1, wherein the urethane-based binder comprises at least one unit selected from among units derived from polyether-based polyols and polyester-based polyols.

9. The adhesive film for surface protection according to claim 1, wherein the urethane-based binder is formed of at least one polyisocyanate compound and a polyol comprising 50 wt % to 95 wt % of a polyether-based triol and 5 wt % to 50 wt % of a polyether-based diol.

10. The adhesive film for surface protection according to claim 9, wherein the polyether-based diol has a number average molecular weight of 400 to 10,000, and the polyether-based triol has a number average molecular weight of 400 to 10,000.

11. The adhesive film for surface protection according to claim 1, wherein the urethane-based binder is formed of at least one polyisocyanate compound and a polyol comprising 50 wt % to 90 wt % of a polyether-based triol, 5 wt % to 40 wt % of a polyether-based diol, and 5 wt % to 40 wt % of a polyester-based diol.

12. The adhesive film for surface protection according to claim 11, wherein the polyether-based diol has a number average molecular weight of 400 to 10,000, the polyether-based triol has a number average molecular weight of 400 to 10,000, and the polyester-based diol has a number average molecular weight of 1,000 to 5,000.

13. The adhesive film for surface protection according to claim 1, wherein the curable component further comprises a polyol.

14. The adhesive film for surface protection according to claim 13, wherein the polyol is present in an amount of greater than 0 to 70 parts by weight relative to 100 parts by weight of the urethane-based binder.

15. The adhesive film for surface protection according to claim 13, wherein the polyol comprises at least one selected from among a polyether-based polyol, a polyester-based polyol, a polycaprolactone-based polyol, and a polycarbonate-based polyol.

16. The adhesive film for surface protection according to claim 1, wherein the curing agent comprises an isocyanate-based curing agent and is present in an amount of 1 part by weight to 10 parts by weight relative to 100 parts by weight of the curable component.

17. The adhesive film for surface protection according to claim 1, wherein the curing agent comprises an isocyanurate type isocyanate-based curing agent.

18. The adhesive film for surface protection according to claim 1, further comprising;
at least one selected from among a crosslinking catalyst, a leveling agent, an antistatic agent, an antioxidant, and a retarder.

19. An optical member comprising: an optical film; and the adhesive film for surface protection according to claim 1 formed on a surface of the optical film.
